(19) United States
(12) Patent Application Publication
(10) Pub. No.: US 2012/0262867 A1
(43) Pub. Date: Oct. 18, 2012

(54) FOLDABLE KEYBOARD ASSEMBLY AND PORTABLE ELECTRONIC MODULE THEREOF

(76) Inventors: Chia-Hung Liu, Taoyuan (TW); Ting-Kuei Cheng, Taoyuan (TW); Chang-En Sun, Taoyuan (TW)

(21) Appl. No.: 13/434,826

(22) Filed: Mar. 29, 2012

(30) Foreign Application Priority Data
Apr. 13, 2011 (TW) 100206447

(51) Int. Cl. G06F 1/16; H05K 7/00

(52) U.S. Cl. 361/679.16; 361/679.01

(57) ABSTRACT

A foldable keyboard assembly includes a foldable structure and a rotary foldable keyboard. The foldable structure includes a first foldable member, a third foldable member, and a second foldable member foldably disposed therebetween. A portable electronic device is detachably disposed on the third foldable member. The rotary foldable keyboard includes a support board, a first keyboard, and a second keyboard. The support board is disposed on the first foldable member. The first keyboard and the second keyboard are movably disposed on the support board and pivotally connected to each other. When the first keyboard and the second keyboard are folded relatively, they are contained in the foldable structure. When the first keyboard and the second keyboard are expanded relatively, the second foldable member can bend relative to the third foldable member for supporting the portable electronic device to abut against a side of the rotary foldable keyboard.

### BACKGROUND OF THE INVENTION

1. Field of the Invention

The present invention relates to a foldable keyboard assembly and a portable electronic module thereof, and more specifically, to a foldable keyboard assembly capable of supporting a portable electronic device to abut against a side of a rotary foldable keyboard and a portable electronic module thereof.

2. Description of the Prior Art

In recent years, a touch panel has been gradually applied to a portable electronic device, such as a PDA (Personal Digital Assistant), a tablet computer, or an electronic reader. Since the touch panel on the portable electronic device may be damaged easily when receiving a sudden impact, the portable electronic device is usually contained in a foldable protection cover for protection of the portable electronic device and the touch panel.

However, if a user wants to combine the portable electronic device having the touch panel with an input device for having a sense like operating a desktop computer or a notebook so that the user can operate the portable electronic device comfortably over a long period of time, the user needs to utilizes an additional support frame to support the portable electronic device, so as to cause a strenuous and time-consuming assembly process. Furthermore, since the size of the input device does not always conform to the size of the foldable protection cover and there is no integration design applied to assembly of the input device and the foldable protection cover, it may cause the user much inconvenience in carrying and storage.

### SUMMARY OF THE INVENTION

The present invention provides a foldable keyboard assembly including a foldable structure and a rotary foldable keyboard. The foldable structure includes a first foldable member, a second foldable member, and a third foldable member. The second foldable member is foldably connected to the first foldable member. The third foldable member is foldably connected to the second foldable member. A portable electronic device is detachably disposed on the third foldable member. The rotary foldable keyboard is disposed on the foldable structure. The rotary foldable keyboard includes a support board, a first keyboard, and a second keyboard. The support board is disposed on the first foldable member. The first keyboard is movably disposed on the support board. The second keyboard is movably disposed on the support board and pivotally connected to the first keyboard, for being folded or expanded with the first keyboard. When the first keyboard and the second keyboard are folded relatively, the first keyboard and the second keyboard are contained in the foldable structure. When the first keyboard and the second keyboard are expanded relatively, the second foldable member can bend relative to the third foldable member for supporting the portable electronic device to abut against a side of the rotary foldable keyboard.

The present invention further provides a portable electronic module including a portable electronic device and a foldable keyboard assembly. The foldable keyboard assembly is used for containing or supporting the portable electronic device. The foldable keyboard assembly includes a foldable structure and a rotary foldable keyboard. The foldable structure includes a first foldable member, a second foldable member, and a third foldable member. The second foldable member is foldably connected to the first foldable member. The third foldable member is foldably connected to the second foldable member. The portable electronic device is detachably disposed on the third foldable member. The rotary foldable keyboard is disposed on the foldable structure. The rotary foldable keyboard includes a support board, a first keyboard, and a second keyboard. The support board is disposed on the first foldable member. The first keyboard is movably disposed on the support board. The second keyboard is movably disposed on the support board and pivotally connected to the first keyboard, for being folded or expanded with the first keyboard. When the first keyboard and the second keyboard are folded relatively, the first keyboard and the second keyboard are contained in the foldable structure. When the first keyboard and the second keyboard are expanded relatively, the second foldable member can bend relative to the third foldable member for supporting the portable electronic device to abut against a side of the rotary foldable keyboard.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a portable electronic module in an expanded state according to an embodiment of the present invention.

FIG. 2 is a top view of a rotary foldable keyboard in the expanded state in FIG. 1.

FIG. 3 is a partial exploded diagram of the rotary foldable keyboard in FIG. 2.

FIG. 4 is a top view of the rotary foldable keyboard in FIG. 2 during its folding process.

FIG. 5 is a top view of the rotary foldable keyboard in FIG. 2 in a folded state.

FIG. 6 is a diagram of the portable electronic module in FIG. 1 in the folded state.

FIG. 7 is a diagram of the portable electronic module 10 in FIG. 6 in a half-expanded state.

FIG. 8 is a top view of a rotary foldable keyboard in the expanded state according to another embodiment of the present invention.

FIG. 9 is bottom view of the rotary foldable keyboard in FIG. 8.

FIG. 10 is a top view of the rotary foldable keyboard in FIG. 8 during its folding process.

FIG. 11 is a top view of the rotary foldable keyboard in FIG. 8 in the folded state.

### DETAILED DESCRIPTION

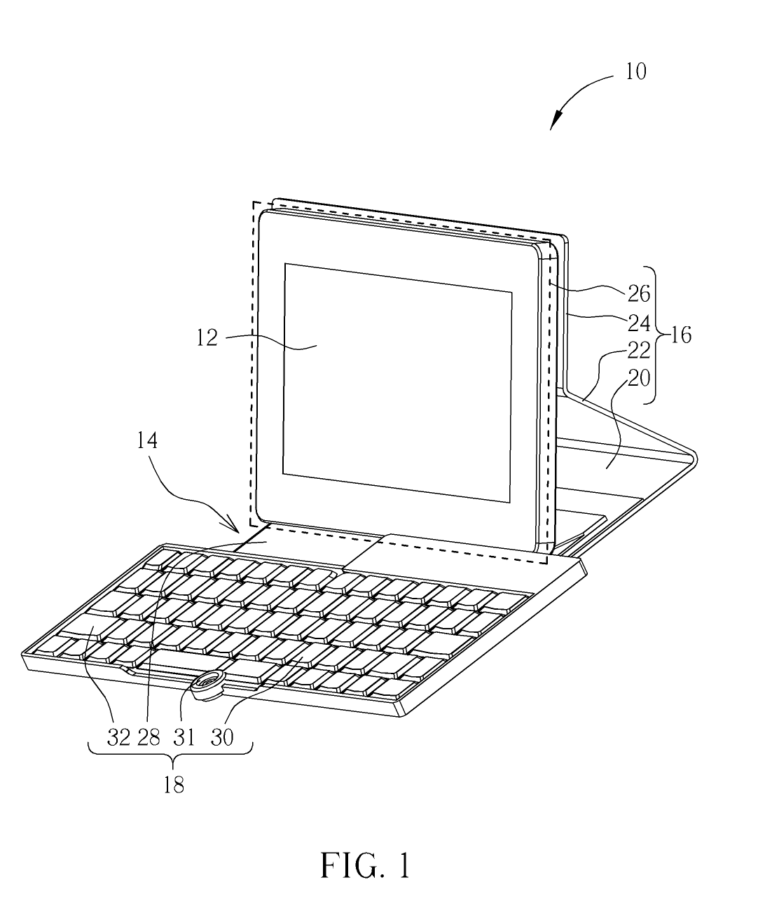

Please refer to FIG. 1, which is a diagram of a portable electronic module 10 in an expanded state according to an embodiment of the present invention. As shown in FIG. 1, the portable electronic module 10 includes a portable electronic device 12 and a foldable keyboard assembly 14. In this embodiment, the portable electronic device 12 is preferably a tablet computer, but is not limited thereto, meaning that the portable electronic device 12 can be other portable electronic device (e.g. a PDA or an electronic reader). The foldable keyboard assembly 14 is used for containing or supporting the portable electronic device 12. The foldable keyboard assembly 14 includes a foldable structure 16 and a rotary foldable keyboard 18. The foldable structure 16 includes a first foldable member 20, a second foldable member 22, a third foldable member 24, and a protection cover 26. The second foldable member 22 is foldably connected to the first foldable member 20. The third foldable member 24 is foldably connected to the second foldable member 22. The protection cover 26 (depicted by dotted lines in FIG. 1) is disposed on the third foldable member 24 for containing the portable electronic device, so as to achieve the purpose that the portable electronic device 12 can be detachably disposed on the third foldable member 24. To be noted, the foldable keyboard assembly 14 can also utilize other fixing design instead of disposal of the protection cover 26. For example, the third foldable member 24 can have an engaging slot formed thereon to be engaged with a corner of the portable electronic device 12.

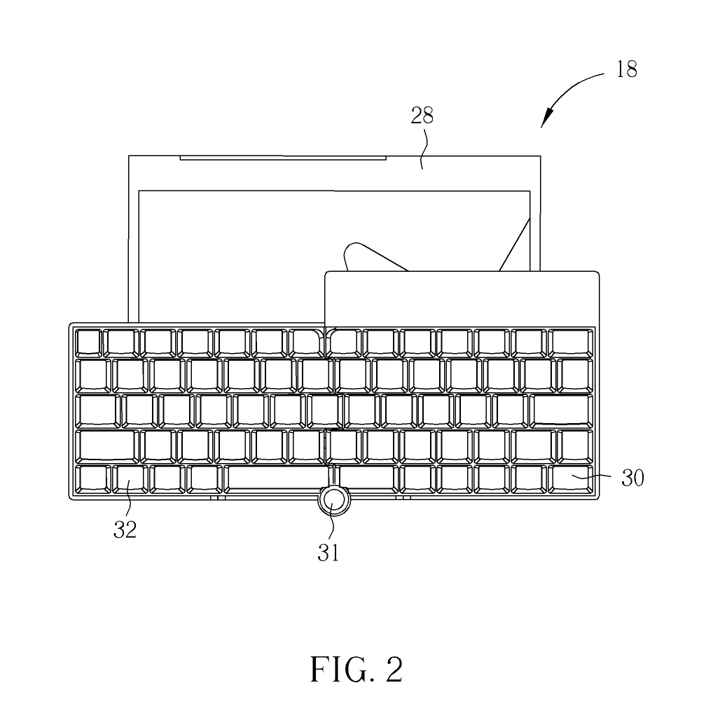

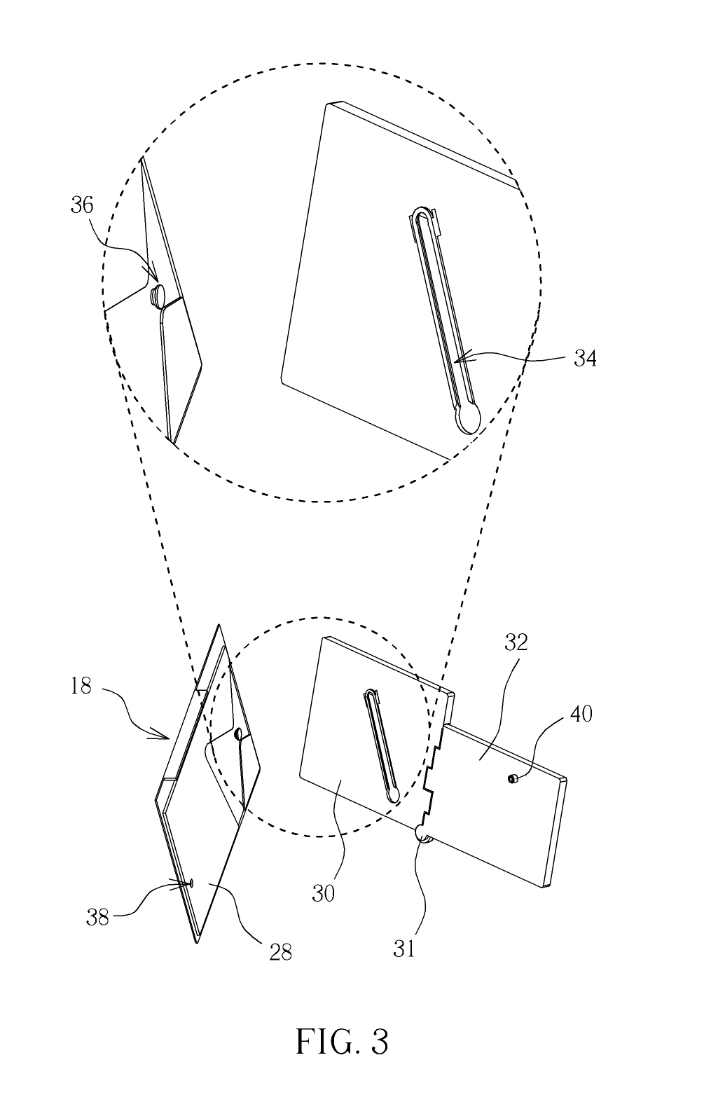

Description for the mechanical design and the operations of the rotary foldable keyboard 18 is provided as follows. Please refer FIG. 2 and FIG. 3. FIG. 2 is a top view of the rotary foldable keyboard 18 in the expanded state in FIG. 1. FIG. 3 is a partial exploded diagram of the rotary foldable keyboard 18 in FIG. 2. As shown in FIG. 2 and FIG. 3, the rotary foldable keyboard 18 includes a support board 28, a first keyboard 30, a pivot member 31, a second keyboard 32, a slot 34, and a protruding portion 36. The first keyboard 30 and the second keyboard 32 are movably disposed on the support board 28. The pivot member 31 is used for being pivotally connected to the first keyboard 30 and the second keyboard 32, so as to make the first keyboard 30 and the second keyboard 32 capable of rotating relatively. The support board 28 has a first pivot portion 38. The second keyboard 32 has a second pivot portion 40. The second pivot portion 40 is used for being pivotally connected to the first pivot portion 38. Accordingly, the second keyboard 32 can be rotated relative to the support board 28.

In this embodiment, the slot 34 is formed on the first keyboard 30. The protruding portion 36 is disposed on the support board 28 opposite to the slot 34 (as shown in FIG. 3). In another embodiment, the slot 34 can be formed on the support board 28 instead, and the protruding portion 36 can be disposed on the first keyboard 30 opposite to the slot 34. In other words, disposal of the slot 34 and the protruding portion 36 is not limited to FIG. 3.

When the first keyboard 30 and the second keyboard 32 are disposed on the support board 28, the protruding portion 36 is movably engaged with the slot 34 and the first pivot portion 38 is pivotally connected to the second pivot portion 40. When the first keyboard 30 and the second keyboard 32 are rotated relatively, the protruding portion 36 is rotated and moved in the slot 34 correspondingly and the second pivot portion 40 is rotated relative to the first pivot portion 38, so that the first keyboard 30 and the second keyboard 32 can be folded or expanded relatively on the support board 28.

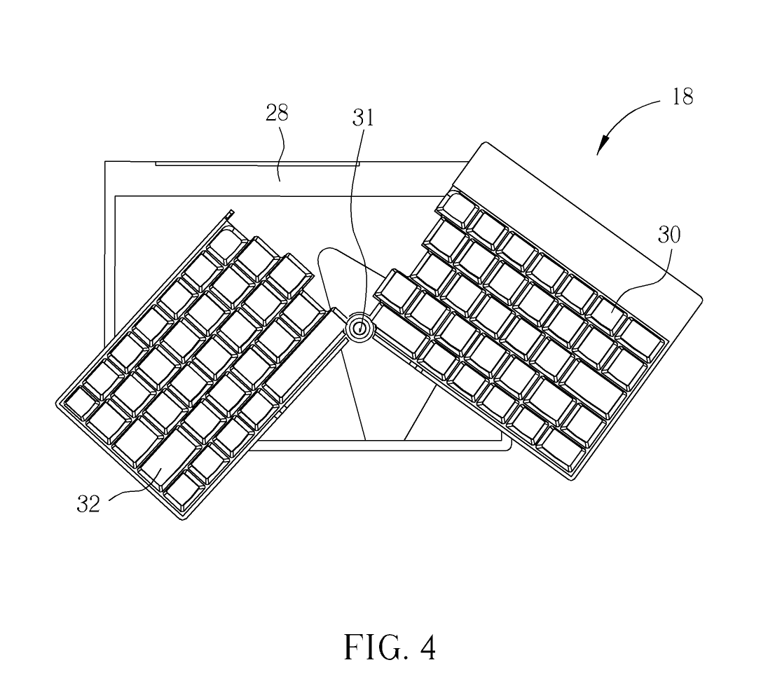

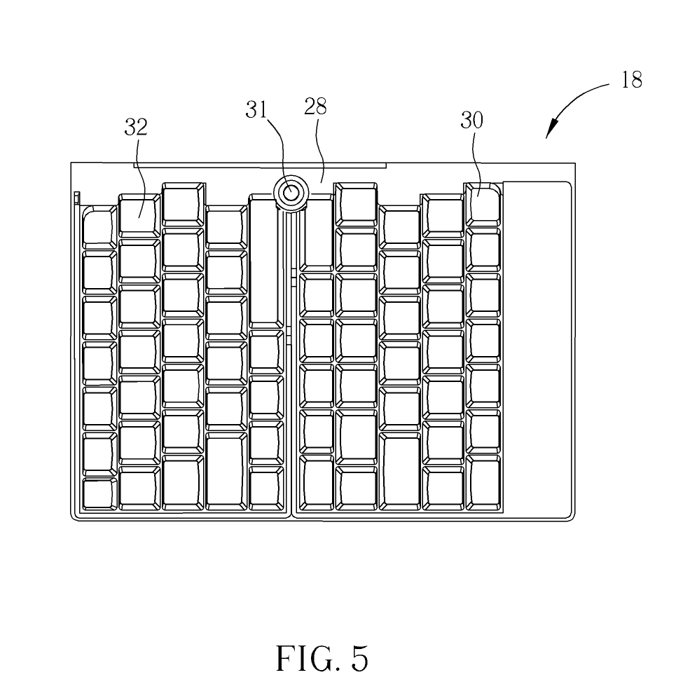

Further detailed description for the folding design of the rotary foldable keyboard 18 is provided as follows. Please refer to FIG. 4 and FIG. 5. FIG. 4 is a top view of the rotary foldable keyboard 18 in FIG. 2 during its folding process. FIG. 5 is a top view of the rotary foldable keyboard 18 in FIG. 2 in a folded state. When a user wants to fold up the rotary foldable keyboard 18 in FIG. 2, the user just needs to push the first keyboard 30 and the second keyboard 32 to rotate relative to each other (as shown in FIG. 4) until the first keyboard 30 and second keyboard 32 are folded relatively on the support board 28. At this time, as shown in FIG. 5, the first keyboard 30 and the second keyboard 32 are completely located within an area coverage of the support board 28.

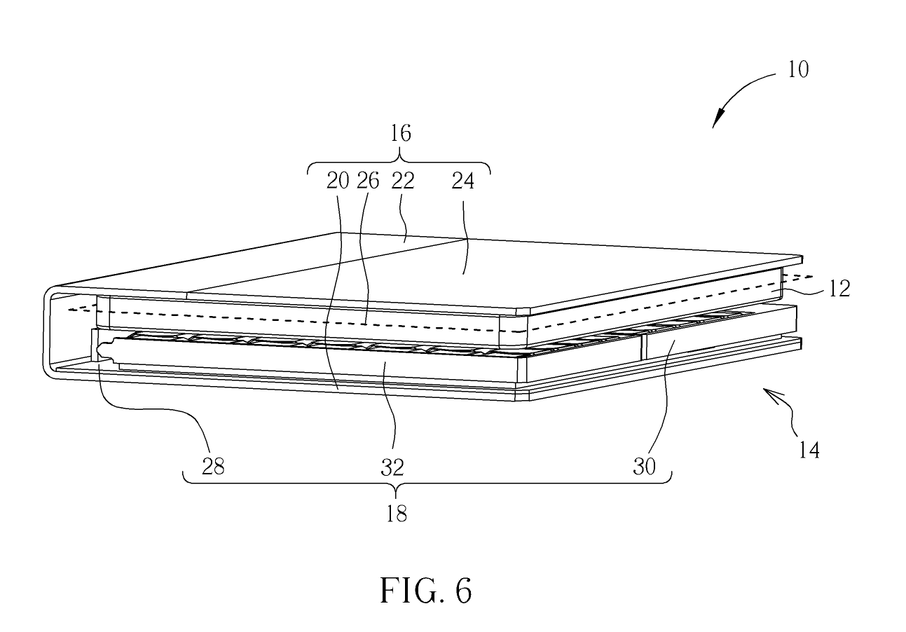

In the following, folding and expanding operations of the portable electronic module 10 are described in detail. At first, please refer to FIG. 6, which is a diagram of the portable electronic module 10 in FIG. 1 in the folded state. When the portable electronic module 10 is in the folded state as shown in FIG. 6, the first keyboard 30 and the second keyboard 32 are folded relatively on the support board 28 and contained together with the portable electronic device 12 in the foldable structure 16 for convenient storage or carrying.

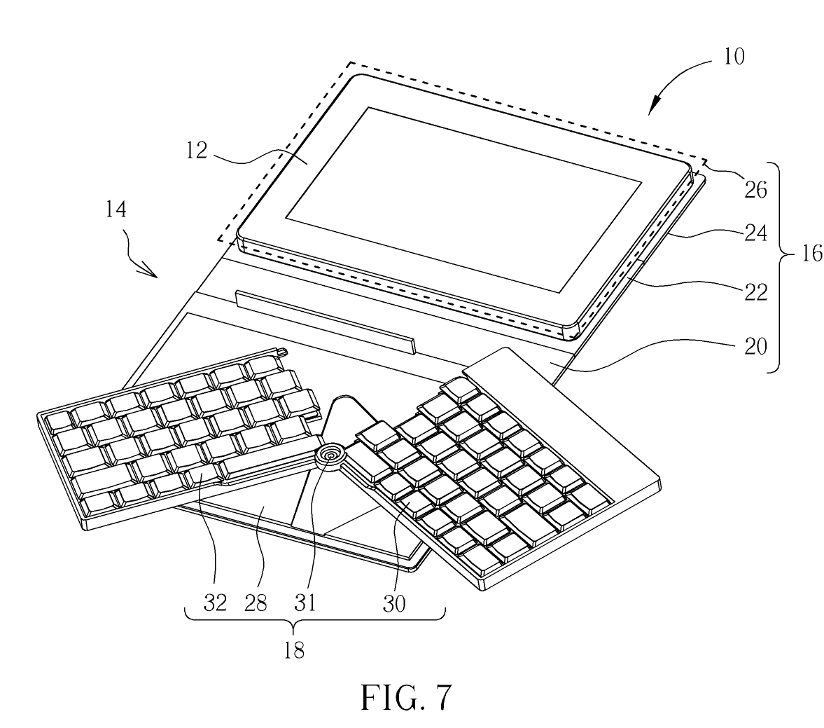

Next, please refer to FIG. 1, FIG. 6, and FIG. 7. FIG. 7 is a diagram of the portable electronic module 10 in FIG. 6 in a half-expanded state. When the user wants to expand the portable electronic module 10 for performing a text input operation, the user just needs to spread the foldable structure 16 from a position as shown in FIG. 6 to a position as shown in FIG. 7, and then push the first keyboard 30 and the second keyboard 32 to rotate relatively until the first keyboard 30 and the second keyboard 32 are expanded relatively from a position as shown in FIG. 5 to a position as shown in FIG. 2 through a position as shown in FIG. 4. Subsequently, after the second foldable member 22 and the third foldable member 24 are bent to a position as shown in FIG. 1 relative to the first foldable member 20, the foldable structure 16 can support the portable electronic module 12 to abut against a side of the rotary foldable keyboard 18. Accordingly, the expanding operation of the portable electronic module 10 is completed so as to make the portable electronic module 10 expanded as shown in FIG. 1. In such a manner, the user can use the expanded rotary foldable keyboard 18 to perform the related operations of the portable electronic module 10 (e.g. a text input operation or a cursor control operation), so as to have a sense like operating a desktop computer or a notebook.

On the other hand, if the user wants to fold up the portable electronic module 10 in the expanded state as shown in FIG. 1, the user just needs to spread the foldable structure 16 in FIG. 1 (as shown in FIG. 7), and then push the first keyboard 30 and the second keyboard 32 to rotate relatively until the first keyboard 30 and the second keyboard 32 are folded relatively from the position as shown in FIG. 2 to the position as shown in FIG. 5 through the position as shown in FIG. 4. Finally, after the second foldable member 22 and the third foldable member 24 are bent to a position where the second foldable member 22 and the third foldable member 24 are stacked on the rotary foldable keyboard 18 (as shown in FIG. 6) relative to the first foldable member 20, the folding operation of the portable electronic module 10 is completed accordingly so as to make the portable electronic module 10 folded as shown in FIG. 6 for convenient storage or carrying.

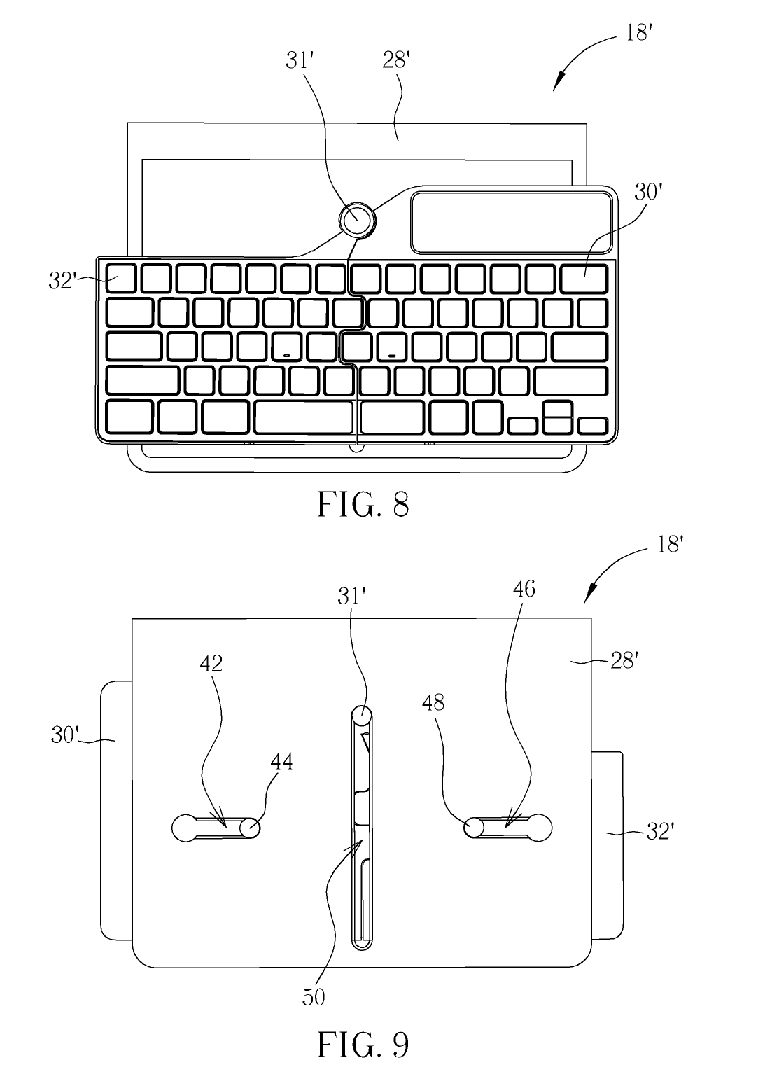

It should be mentioned that the folding and expanding designs of the rotary foldable keyboard 18 are not limited to the aforesaid embodiment. For example, please refer to FIG. 8 and FIG. 9. FIG. 8 is a top view of a rotary foldable keyboard 18′ in the expanded state according to another embodiment of the present invention. FIG. 9 is bottom view of the rotary foldable keyboard 18′ in FIG. 8. The rotary foldable keyboard 18′ includes a support board 28′, a first keyboard 30′, a pivot member 31′, a second keyboard 32′, a first slot 42, and a first protruding portion 44, a second slot 46, and a second protruding portion 48. The first keyboard 30′ and the second keyboard 32′ are movably disposed on the support board 28′. The pivot member 31′ is used for being pivotally connected to the first keyboard 30′ and the second keyboard 32′, so as to make the first keyboard 30′ and the second keyboard 32′ capable of rotating relatively.

In this embodiment, as shown in FIG. 9, the first slot 42 is formed on the support board 28′, the first protruding portion 44 is disposed on the first keyboard 30′ opposite to the first slot 42, the second slot 46 is formed on the support board 28′, and the second protruding portion 48 is disposed on the second keyboard 32′ opposite to the second slot 46. Similarly, disposal of the first slot 42, the first protruding portion 44, the second slot 46, and the second protruding portion 48 is not limited to FIG. 9.

When the first keyboard 30′ and the second keyboard 32′ are disposed on the support board 28′, the first protruding portion 44 is movably engaged with the first slot 42 and the second protruding portion 48 is movably engaged with the second slot 46. When the first keyboard 30′ and the second keyboard 32′ are rotated relative to the pivot member 31′, the first protruding portion 44 and the second protruding portion 48 are rotated and moved in the first slot 42 and the second slot 46 respectively, so that the first keyboard 30′ and the second keyboard 32′ can be folded or expanded relatively on the support board 28′.

In this embodiment, the support board 28′ can further have a third slot 50. As shown in FIG. 9, the third slot 50 is located between the first slot 42 and the second slot 46 and one end of the pivot member 31′ is movably disposed in the third slot 50. Furthermore, the first slot 42 is parallel to the second slot 46, and the third slot 50 is perpendicular to the first slot 42 and the second slot 46. In such a manner, when the first keyboard 31′ and the second keyboard 32′ are folded or expanded relatively on the support board 28′, the third slot 50 can constrain an end of the pivot member 31′ so that the end of the pivot member 31′ can only move back and forth in third slot 50. In other words, the third slot 50 can be cooperated with the pivot member 31′ so as to make folding or expanding of the first keyboard 30′ relative to the second keyboard 32′ steadier.

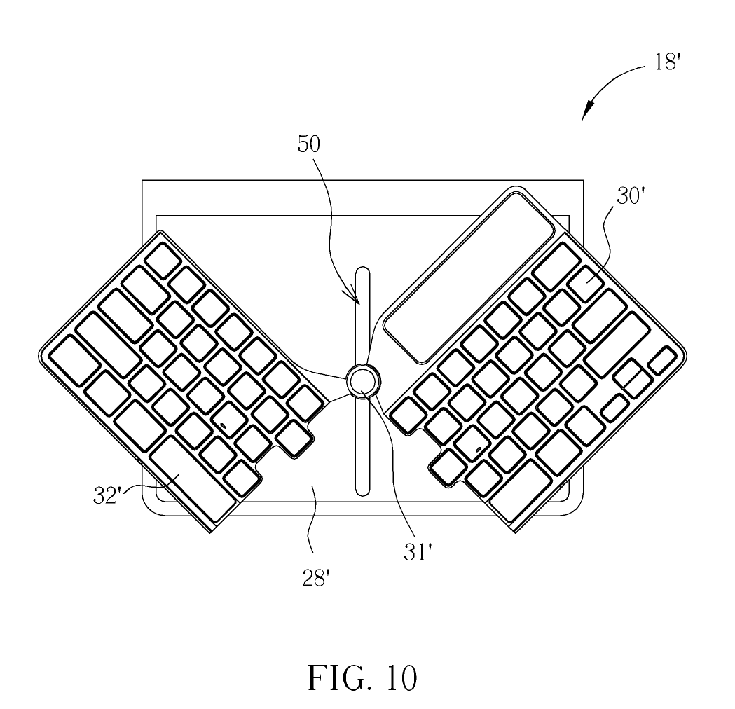

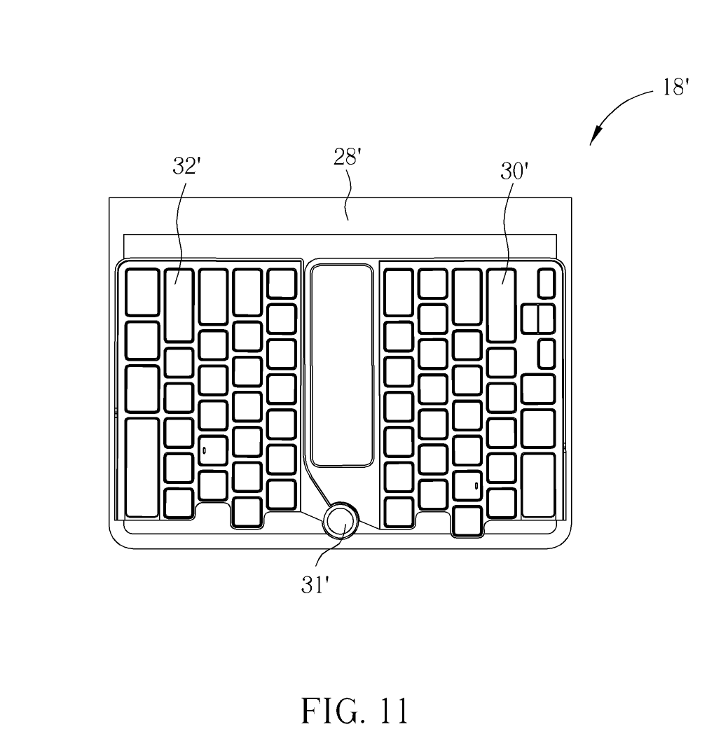

Please refer to FIG. 10 and FIG. 11. FIG. 10 is a top view of the rotary foldable keyboard 18′ in FIG. 8 during its folding process. FIG. 11 is a top view of the rotary foldable keyboard 18′ in FIG. 8 in the folded state. When the user wants to fold up the rotary foldable keyboard 18′ in FIG. 8, the user just needs to push the first keyboard 30′ and the second keyboard 32′ to rotate relatively until the first keyboard 30′ and the second keyboard 32′ are folded relatively from a position as shown in FIG. 8 to a position as shown in FIG. 11 through a position as shown in FIG. 10. Similarly, the expanding operation of the rotary foldable keyboard 18′ can be reasoned by analogy according to the said folding operation of the rotary foldable keyboard 18′. As for description of the related operations of the rotary foldable keyboard 18′ and the foldable structure 16, it is similar to that mentioned in the aforesaid embodiment and then omitted herein.

Compared with the prior art, the present invention utilizes the integration design that the rotary foldable keyboard is disposed on the foldable protection cover, to allow that a user can rotate the first keyboard and the second keyboard to be completely contained in the foldable protection cover or be expanded relatively so that the expanded rotary foldable keyboard can support the portable electronic device cooperatively with the foldable protection cover. In such a manner, after completing the expanding operation of the portable electronic module, the user can use the expanded rotary foldable keyboard to directly operate the portable electronic device without performing additional installation of a support frame. Thus, the present invention can improve convenience of the portable electronic module in use. In addition, the user can store or carry the portable electronic module conveniently when the portable electronic module is in the folded state.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A foldable keyboard assembly comprising:
a foldable structure comprising:
a first foldable member;
a second foldable member foldably connected to the first foldable member; and
a third foldable member foldably connected to the second foldable member, a portable electronic device being detachably disposed on the third foldable member; and
a rotary foldable keyboard disposed on the foldable structure, the rotary foldable keyboard comprising:
a support board disposed on the first foldable member;
a first keyboard movably disposed on the support board; and
a second keyboard movably disposed on the support board and pivotally connected to the first keyboard, for being folded or expanded with the first keyboard;
wherein when the first keyboard and the second keyboard are folded relatively, the first keyboard and the second keyboard are contained in the foldable structure; when the first keyboard and the second keyboard are expanded relatively, the second foldable member can bend relative to the third foldable member for supporting the portable electronic device to abut against a side of the rotary foldable keyboard.

2. The foldable keyboard assembly of claim 1, wherein the support board has a first pivot portion, the second keyboard has a second pivot portion, the second pivot portion is pivotally connected to the first pivot portion, and the rotary foldable keyboard further comprises:
a slot formed on the first keyboard; and
a protruding portion disposed on the support board and movably engaged with the slot;
wherein when the first keyboard and the second keyboard are rotated relatively, the protruding portion is rotated and moved in the slot and the second pivot portion is rotated relative to the first pivot portion, so as to make the first keyboard and the second keyboard folded or expanded relatively on the support board.

3. The foldable keyboard assembly of claim 2, wherein the rotary foldable keyboard further comprises a pivot member pivotally connected to the first keyboard and the second keyboard.

4. The foldable keyboard assembly of claim 1, wherein the rotary foldable keyboard further comprises:
a first slot formed on the support board;
a first protruding portion disposed on the first keyboard and movably engaged with the first slot;
a second slot formed on the support board;
a second protruding portion disposed on the second keyboard and movably engaged with the second slot;
wherein when the first keyboard and the second keyboard are rotated relatively, the first protruding portion and the second protruding portion are rotated and moved in the first slot and the second slot respectively, so as to make the first keyboard and the second keyboard folded or expanded relatively on the support board.

5. The foldable keyboard assembly of claim 4, wherein the rotary foldable keyboard further comprises a pivot member pivotally connected to the first keyboard and the second keyboard.

6. The foldable keyboard assembly of claim 5, wherein the support board further has a third slot located between the first slot and the second slot, and an end of the pivot member is movably disposed in the third slot.

7. The foldable keyboard assembly of claim 1, wherein when the first keyboard and the second keyboard are folded relatively on the support board, the first keyboard and the second keyboard are completely located within an area coverage of the support board.

8. The foldable keyboard assembly of claim 1, wherein the foldable structure further comprises:
a protection cover disposed on the third foldable member for containing the portable electronic device.

9. A portable electronic module comprising:
a portable electronic device; and
a foldable keyboard assembly for containing or supporting the portable electronic device, the foldable keyboard assembly comprising:
a foldable structure comprising:
a first foldable member;
a second foldable member foldably connected to the first foldable member; and
a third foldable member foldably connected to the second foldable member, the portable electronic device being detachably disposed on the third foldable member; and
a rotary foldable keyboard disposed on the foldable structure, the rotary foldable keyboard comprising:
a support board disposed on the first foldable member;
a first keyboard movably disposed on the support board; and
a second keyboard movably disposed on the support board and pivotally connected to the first keyboard, for being folded or expanded with the first keyboard;
wherein when the first keyboard and the second keyboard are folded relatively, the first keyboard and the second keyboard are contained in the foldable structure; when the first keyboard and the second keyboard are expanded relatively, the second foldable member can bend relative to the third foldable member for supporting the portable electronic device to abut against a side of the rotary foldable keyboard.

10. The portable electronic module of claim 9, wherein the support board has a first pivot portion, the second keyboard has a second pivot portion, the second pivot portion is pivotally connected to the first pivot portion, and the rotary foldable keyboard further comprises:
a slot formed on the first keyboard; and
a protruding portion disposed on the support board and movably engaged with the slot;
wherein when the first keyboard and the second keyboard are rotated relatively, the protruding portion is rotated and moved in the slot and the second pivot portion is rotated relative to the first pivot portion, so as to make the first keyboard and the second keyboard folded or expanded relatively on the support board.

11. The portable electronic module of claim 10, wherein the rotary foldable keyboard further comprises a pivot member pivotally connected to the first keyboard and the second keyboard.

12. The portable electronic module of claim 9, wherein the rotary foldable keyboard further comprises:
a first slot formed on the support board;
a first protruding portion disposed on the first keyboard and movably engaged with the first slot;
a second slot formed on the support board;
a second protruding portion disposed on the second keyboard and movably engaged with the second slot;
wherein when the first keyboard and the second keyboard are rotated relatively, the first protruding portion and the second protruding portion are rotated and moved in the first slot and the second slot respectively, so as to make the first keyboard and the second keyboard folded or expanded relatively on the support board.

13. The portable electronic module of claim 12, wherein the rotary foldable keyboard further comprises a pivot member pivotally connected to the first keyboard and the second keyboard.

14. The portable electronic module of claim 13, wherein the support board further has a third slot located between the first slot and the second slot, and an end of the pivot member is movably disposed in the third slot.

15. The portable electronic module of claim 9, wherein when the first keyboard and the second keyboard are folded relatively on the support board, the first keyboard and the second keyboard are completely located within an area coverage of the support board.

16. The portable electronic module of claim 9, wherein the foldable structure further comprises:
a protection cover disposed on the third foldable member for containing the portable electronic device.

17. The portable electronic module of claim 9, wherein the portable electronic device is a tablet computer.
